(19) United States
(12) Patent Application Publication
(10) Pub. No.: US 2019/0027619 A1
(43) Pub. Date: Jan. 24, 2019

(54) SOLAR CELL

(71) Applicant: Panasonic Intellectual Property Management Co., Ltd., Osaka (JP)

(72) Inventor: Motohide Kai, Osaka (JP)

(73) Assignee: Panasonic Intellectual Property Management Co., Ltd., Osaka (JP)

(21) Appl. No.: 16/137,039

(22) Filed: Sep. 20, 2018

Related U.S. Application Data
(63) Continuation of application No. PCT/JP2016/087617, filed on Dec. 16, 2016.

(30) Foreign Application Priority Data
Mar. 25, 2016 (JP) 2016-061965

(51) Int. Cl. H01L 31/0216; H01L 31/0747

(52) U.S. Cl. CPC H01L 31/02167; H01L 31/0747

(57) ABSTRACT

A solar cell includes an n-type crystalline silicon wafer, a first silicon nitride layer formed over a light receiving surface of the wafer, an n-type amorphous silicon layer formed over a first region of a back surface, a second silicon nitride layer formed over a part of the n-type amorphous silicon layer, and a p-type amorphous silicon layer formed over a second region of the back surface of the n-type crystalline silicon wafer and over the second silicon nitride layer. The second silicon nitride layer has a higher index of refraction than the first silicon nitride layer.

### INCORPORATION BY REFERENCE

This application is a U.S. continuation application of PCT International Patent Application Number PCT/JP2016/087617, filed Dec. 16, 2016. claiming the benefit of priority of Japanese Patent Application Number 2016-061965, filed Mar. 25, 2016, the entire contents of which are hereby incorporated by reference.

### TECHNICAL FIELD

The present disclosure relates to a solar cell.

### BACKGROUND

In the related art, a solar cell is known which comprises an n-type amorphous silicon layer and a p-type amorphous silicon layer respectively provided over a back surface of a crystalline silicon wafer, and a silicon nitride layer which is an insulating layer interposed between the silicon layers (for example, refer to Japanese Unexamined Patent Application Publication No. 2016-6841 A). In the solar cell of Japanese Unexamined Patent Application Publication No. 2016-6841 A, electrodes are provided only on the side of the back surface of the silicon wafer. In addition, in the solar cell, a diffusion prevention film which prevents diffusion of nitrogen into the silicon layers is further provided between the silicon nitride layer and the amorphous silicon layers, to suppress degradation of passivation performance at the interface between the amorphous silicon layers and the silicon wafer.

By employing a backside junction type structure in which the electrodes are provided only on the side of the back surface of the silicon wafer as in the solar cell of Japanese Unexamined Patent Application Publication No. 2016-6841 A, an amount of incident light can be increased compared to a case where the electrode is provided on the side of a light receiving surface of the wafer.

In a solar cell, it is important to improve an output characteristic by improving an open voltage and a short-circuit current, along with an increase in the amount of light incident on the silicon wafer.

### SUMMARY

According to one aspect of the present disclosure, there is provided a solar cell including: a crystalline silicon wafer; a first silicon nitride layer including silicon nitride as a main composition, and formed over a light receiving surface of the crystalline silicon wafer; a first amorphous silicon layer of a first conductivity type, formed over a first region of a back surface of the crystalline silicon wafer; a second silicon nitride layer including silicon nitride as a main composition, and formed over a part of the first amorphous silicon layer; and a second amorphous silicon layer of a second conductivity type, formed over a second region of the back surface of the crystalline silicon wafer and over the second silicon nitride layer, wherein the second silicon nitride layer has a higher index of refraction than the first silicon nitride layer

### ADVANTAGEOUS EFFECTS OF INVENTION

The solar cell according to the present disclosure has a high open voltage and a high short-circuit current, and has a superior output characteristic. In addition, an amount of light incident on the silicon wafer is large, and a high power generation efficiency can be obtained.

### BRIEF DESCRIPTION OF DRAWINGS

The figures depict one or more implementations in accordance with the present teaching, by way of example only, not by way of limitations. In the figures, like reference numerals refer to the same or similar elements.

FIG. 1 is a diagram of an example solar cell according to an embodiment of the present disclosure, viewed from a back surface side.

FIG. 2 is a diagram showing a part of a cross section along a line AA of FIG. 1.

FIG. 3 is a diagram showing a relationship between an index of refraction of a second silicon nitride layer and an open voltage of a cell.

FIG. 4 is a diagram showing a relationship between an index of refraction of a second silicon nitride layer and a hydrogen concentration.

FIG. 5A is a diagram showing a relationship between a hydrogen concentration of a second silicon nitride layer, and hydrogen concentrations of an n-type amorphous silicon layer and a first passivation layer.

FIG. 5B is a diagram showing an example of the related art.

FIG. 6A is a diagram for explaining an example manufacturing method of a solar cell according to an embodiment of the present disclosure.

FIG. 6B is a diagram for explaining an example manufacturing method of a solar cell according to an embodiment of the present disclosure.

FIG. 6C is a diagram for explaining an example manufacturing method of a solar cell according to an embodiment of the present disclosure.

FIG. 6D is a diagram for explaining an example manufacturing method of a solar cell according to an embodiment of the present disclosure.

FIG. 6E is a diagram for explaining an example manufacturing method of a solar cell according to an embodiment of the present disclosure.

### DESCRIPTION OF EMBODIMENTS

The present inventors have undertaken reviews and studies with a view to further improving the output characteristic of the solar cell, and found a new cell structure in which an index of refraction of a silicon nitride layer over a back surface side (second silicon nitride layer) is set higher than an index of refraction of a silicon nitride layer over a light receiving surface side (first silicon nitride layer). With such a structure, the open voltage and the short-circuit current can be improved without reducing the amount of incident light. The present inventors have found that the output characteristic of the solar cell can be improved by increasing the index of refraction of the silicon nitride layer. However, when the index of refraction of the silicon nitride layer is increased, an amount of absorption of light, in particular, light of a short wavelength, is increased. In consideration of this, in the solar cell of the present disclosure, the index of refraction of the first silicon nitride layer over the light receiving surface side is not increased, and only the index of refraction of the second silicon nitride layer over the back surface side is increased, to improve the output characteristic without reducing the amount of light incident on the silicon wafer.

In the solar cell according to the present disclosure, it may be considered that, by increasing the index of refraction of the second silicon nitride layer, the passivation performance at the interface between the silicon wafer and the first amorphous silicon layer is improved, which consequently results in an improvement of the output characteristic. As will be described later in detail, as a factor of improvement of the passivation performance, a factor may be considered in which hydrogen contained in the second silicon nitride layer diffuses to the first amorphous silicon layer and a hydrogen concentration of the first amorphous silicon layer is increased.

An example solar cell according to an embodiment of the present disclosure will now be described in detail with reference to the drawings. The solar cell according to the present disclosure is not limited to the embodiment described below. Drawings referred to in the description of the embodiment are schematically shown, and a size, a ratio, or the like of constituent elements drawn in the drawings should be determined in reference to the following description.

In the present disclosure, a description of “approximately” is intended to include, for example, in the case of “approximate entire region”, not only the entire region but also a region substantially recognized as the entire region. In addition, the description of “formed over” is intended to include, for example, in the case of the light receiving surface of the silicon wafer, not only a case where the first silicon nitride layer is directly formed over the light receiving surface of the wafer, but also a case where the first silicon nitride layer is formed over the light receiving surface with another layer therebetween. An n-type dopant refers to an impurity which functions as a donor, and a p-type dopant refers to an impurity which functions as an acceptor.

In the embodiment described below, as a crystalline silicon wafer, an n-type crystalline silicon wafer doped with an n type will be exemplified. Alternatively, for the crystalline silicon wafer, a p-type crystalline silicon wafer doped with a p type may be employed. In this case, as a first amorphous silicon layer of a first conductivity type, a p-type amorphous silicon layer including p-type amorphous silicon as a main composition is desirably used, and as a second amorphous silicon layer of a second conductivity type, all n-type amorphous silicon layer including n-type amorphous silicon as a main composition is desirably used. For the first silicon nitride layer and the second silicon nitride layer, structures similar to those when the n-type crystalline silicon wafer is used may be employed.

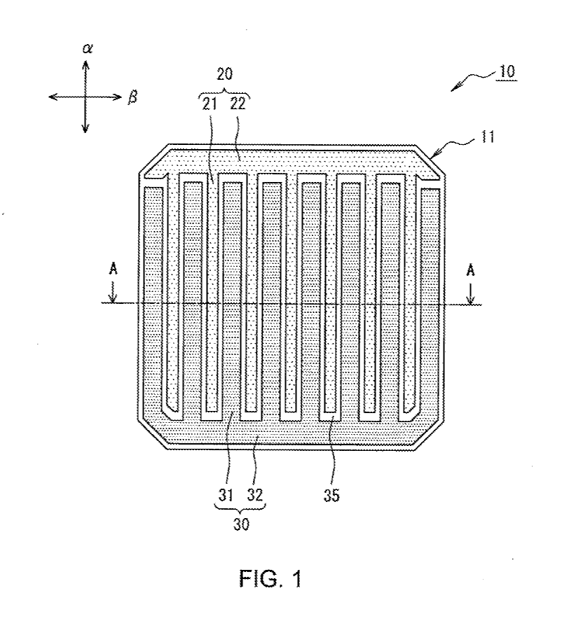

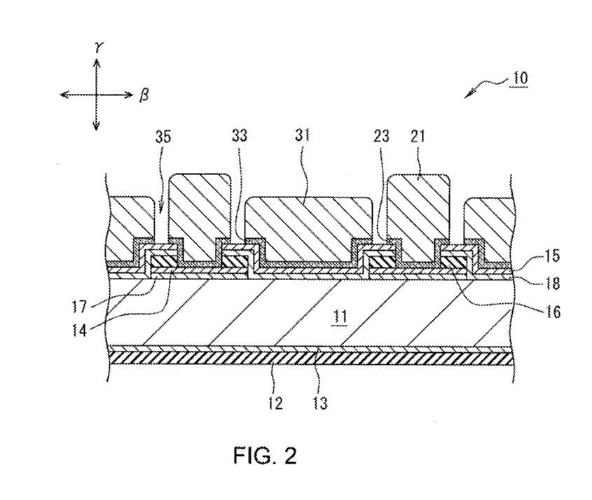

FIG. 1 is a diagram of an example solar cell 10 according to an embodiment of the present disclosure, viewed from a back surface side. FIG. 2 is a diagram showing a part of a cross section along a line AA of FIG. 1. In FIGS. 1 and 2, one direction along the back surface of the solar cell 10 is shown as an α direction, another direction perpendicular to the one direction is shown as a β direction, and a thickness direction of the solar cell 10 is shown as a γ direction.

As shown in FIGS. 1 and 2, the solar cell 10 comprises an n-type crystalline silicon wafer 11, and electrodes formed over a back surface of the n-type crystalline silicon wafer 11. The electrodes include a collector electrode 20 which collects carriers from an n-type region to be described later (n-type region collector electrode) and a collector electrode 30 which collects carriers from a p-type region to be described later (p-type region collector electrode). In the solar cell 10, no electrode is provided over a light receiving surface side of the n-type crystalline silicon wafer 11, and the electrodes are provided only over the back surface side. Here, the “light receiving surface” of the n-type crystalline silicon wafer 11 means a surface onto which the light is primarily incident (exceeding 50%˜100%), and the “back surface” means a surface on an opposite side of the light receiving surface.

The n-type crystalline silicon wafer 11 may be an n-type polycrystalline silicon wafer, but is desirably an n-type monocrystalline silicon wafer. A concentration of n-type dopants in the n-type crystalline silicon wafer 11 is, far example, 1×10¹⁴˜1×10¹⁷ atoms/cm³. For the n-type dopant, in general, phosphorus (P) is used. The n-type crystalline silicon wafer 11 has a surface shape of, for example, an approximate square with a side of 120˜160 mm. The approximate square includes an octagon in which short sides and long sides are alternately continuous, and that has two pairs of long sides which are parallel to each other. A thickness of the n-type crystalline silicon wafer 11 is, for example, 50˜300 μm.

A texture structure (not shown) is desirably formed over a surface of the n-type crystalline silicon wafer 11. The texture structure is a surface unevenness structure for suppressing surface reflection and increasing an amount of absorption of light of the n-type crystalline silicon wafer 11, and is formed over one or both of the light receiving surface and the back surface. Because the solar cell 10 of the present embodiment has a backside junction type structure, the texture structure is desirably provided only over the light receiving surface side of the n-type crystalline silicon wafer 11. The texture structure can be formed by anisotropic etching of a (100) plane of a monocrystalline silicon wafer using an alkaline solution, and an unevenness structure including a pyramid shape with a (111) plane as an inclined surface is formed over the surface of the monocrystalline silicon wafer. A height of the unevenness (projections and depressions) of the texture structure is, for example, 1˜15 μm.

The solar cell 10 comprises a first silicon nitride layer 12 formed over the light receiving surface of the n-type crystalline silicon wafer 11. In the present embodiment, a passivation layer 13 is provided between the n-type crystalline silicon wafer 11 and the first silicon nitride layer 12. In addition, the solar cell 10 comprises an n-type amorphous silicon layer 14, a p-type amorphous silicon layer 15, and a second silicon nitride layer 16, respectively formed over the back surface side of the n-type crystalline silicon water 11. Over the back surface of the n-type crystalline silicon wafer 11, an n-type region doped with the n type is formed by the n-type amorphous silicon layer 14, and a p-type region doped with the p type is formed by the p-type amorphous silicon layer 15.

The n-type amorphous silicon layer 14 is formed over a first region of the back surface of the n-type crystalline silicon wafer 11. Similarly, the p-type amorphous silicon layer 15 is formed over a second region of the back surface of the n-type crystalline silicon wafer 11. In other words, over the back surface of the n-type crystalline silicon wafer 11, a first region in which the n-type amorphous silicon layer 14 is formed becomes the n-type region, and a second region in which the p-type amorphous silicon layer 15 is formed becomes the p-type region. The second silicon nitride layer 16 is formed over a part of the n-type amorphous silicon layer 14. The p-type amorphous silicon layer 15 is formed over the second region and over the second silicon nitride layer 16.

The solar cell 10 further comprises a passivation layer 17 formed between the n-type crystalline silicon wafer 11 and the n-type amorphous silicon layer 14, and a passivation layer 18 formed between the n-type crystalline silicon wafer 11 and the p-type amorphous silicon layer 15. The passivation layer 17 is formed over an approximate entire region of the region in which the n-type amorphous silicon layer 14 is formed (first region) and the passivation layer 18 is formed over an approximate entire region of the region in which the p-type amorphous silicon layer 15 is formed (over the second region and the second silicon nitride layer 16). By providing the passivation layers 17 and 18, the passivation performance at the back surface side of the n-type crystalline silicon wafer 11 can be improved.

The first silicon nitride layer 12 is formed over the light receiving surface of the n-type crystalline silicon wafer 11 with the passivation layer 13 therebetween. The first silicon nitride layer 12 and the passivation layer 13 are formed over an approximate entire region of the light receiving surface of the n-type crystalline silicon wafer 11. When the n-type crystalline silicon wafer 11 having the approximate square shape with a side of 120˜160 mm is used, the passivation layer 13 may cover the entire surface of the approximate square, or may cover an entire surface other than an outer peripheral region less than or equal to 2 mm from edges of the approximate square. A thickness of the first silicon nitride layer 12 is, for example, 50˜150 nm. A thickness of the passivation layer 13 is, for example, 1˜25 nm.

The first silicon nitride layer 12 functions as a protective layer which protects the light receiving surface of the n-type crystalline silicon wafer 11 and the passivation layer 13, and also as a reflection prevention layer which suppresses reflection of the incident light. The first silicon nitride layer 12 is formed with silicon nitride (SiN) as a main composition. The first silicon nitride layer 12 may contain compositions other than SiN such as silicon oxide and silicon oxynitride, but the content of SiN is greater than or equal to 50 weight % with respect to a layer weight, and desirably is greater than or equal to 80 weight %, or about 100 weight %. The first silicon nitride layer 12 can be formed through CVD or sputtering.

The first silicon nitride layer 12 desirably has an index of refraction of light for wavelength of 633 nm of less than 2.1, and desirably has the index of refraction of 1.9˜2.0. The index of refraction of the first silicon nitride layer 12 is measured using spectroscopic ellipsometer (the index of refraction of the second silicon nitride layer 16 is similarly measured). A composition ratio Si/N of SiN of the first silicon nitride layer 12 is, for example 0.8˜1.2. In general, as the Si/N is increased, the index of refraction of SiN is increased. The first silicon nitride layer 12 contains hydrogen, for example, in a concentration of 2×10²¹˜1×10²² atoms/cm³.

The passivation layer 13 suppresses recombination of carriers at the light receiving surface side of the n-type crystalline silicon wafer 11. The passivation layer 13 is desirably formed including, as a main composition, substantially intrinsic silicon (hereinafter also referred to as “i-type amorphous silicon”) or amorphous silicon having a lower dopant concentration than the n-type amorphous silicon layer 14. The passivation layer 13 may be, for example, of a single layer structure of the i-type amorphous silicon layer, or a layered structure of the i-type amorphous silicon layer and an n-type amorphous silicon layer. The passivation layer 13 can be formed through CVD or sputtering.

The n-type amorphous silicon layer 14 is formed over the first region of the back surface of the n-type crystalline silicon wafer 11 with the passivation layer 17 therebetween. The n-type amorphous silicon layer 14 is formed including n-type amorphous silicon as a main composition. A concentration of the n-type dopant in the n-type amorphous silicon layer 14 is, for example, greater than or equal to 1×10²⁰ atoms/cm³. No particular limitation is imposed on the n-type dopant, and generally, phosphorus (P) is used. A thickness of the n-type amorphous silicon layer 14 is, for example, 1˜25 nm, and is desirably 1˜10 nm.

The n-type amorphous silicon layer 14 can be formed through CVD or sputtering. Similarly, the p-type amorphous silicon layer 15, the second silicon nitride layer 16, and the passivation layers 17 and 18 can be formed through CVD or sputtering. As will be described in detail later, the solar cell 10 is manufactured by forming the second silicon nitride layer 16, the passivation layer 18, and the p-type amorphous silicon layer 15 covering the entirety of the n-type amorphous silicon layer 14, and then patterning the layers covering the n-type amorphous silicon layer 14.

The n-type amorphous silicon layer 14 contains hydrogen, for example, in a concentration of 5×10²¹˜1×10²² atoms/cm³. In the n-type amorphous silicon layer 14, it may be considered that, due to diffusion of hydrogen from the second silicon nitride layer 16, the hydrogen concentration is increased. The increase of the hydrogen concentration due to the diffusion of hydrogen can be considered as contributing to the improvement of the passivation performance in the n-type region.

The p-type amorphous silicon layer 15 is formed over the second region of the back surface of the n-type crystalline silicon wafer 11 and over the second silicon nitride layer 16, with the passivation layer 18 therebetween. The p-type amorphous silicon layer 15 is formed including p-type amorphous silicon as a main composition. A concentration of the p-type dopant in the p-type amorphous silicon layer 15 is, for example, greater than or equal to 1×10²⁰ atoms/cm³. No particular limitation is imposed on the p-type dopant, and in general, boron (B) is used. A thickness of the p-type amorphous silicon layer 15 is, for example, 1˜25 nm, and is desirably 1˜10 nm. The p-type amorphous silicon layer 15 contains hydrogen, for example, in a concentration of 5×10²¹˜1×10²² atoms/cm³.

The n-type amorphous silicon layer 14 and the p-type amorphous silicon layer 15 are formed over an approximate entire region of the back surface of the n-type crystalline silicon wafer 11. Because of this, a part of the n-type amorphous silicon layer 14 and a part of the p-type amorphous silicon layer 15 overlap each other, without a gap therebetween. In the present embodiment, the p-type amorphous silicon layer 15 overlaps over the n-type amorphous silicon layer 14 with the second silicon nitride layer 16 therebetween, and the silicon layers are alternately arranged in the β direction of the back surface of the n-type crystalline silicon wafer 11, and formed in a stripe shape. When the n-type amorphous silicon wafer 11 of an approximate square with a side of 120˜160 mm is used, the amorphous silicon layers may cover the entire surface of the approximate square, or cover an entire surface other than an outer peripheral region of less than or equal to 2 mm from edges of the approximate square.

The passivation layer 17 is desirably formed including, as a main composition, substantially intrinsic amorphous silicon (i-type amorphous silicon) or amorphous silicon having a lower n-type dopant concentration than that of the n-type amorphous silicon forming the n-type amorphous silicon layer 14. In addition, the passivation layer 18 is desirably formed including, as a main composition, the i-type amorphous silicon or amorphous silicon having a lower p-type dopant concentration than the p-type amorphous silicon forming the p-type amorphous silicon layer 15. The passivation layers 17 and 18 have, for example, a single layer structure of the i-type amorphous silicon layer, and thicknesses of the passivation layers 17 and 18 are, for example, 1˜25 nm, and desirably 1˜10 nm.

The passivation layer 17 contains hydrogen, for example, in a concentration of 5×10²¹˜1×10²² atoms/cm³. For the passivation layer 17 also, it can be considered that the hydrogen concentration is increased due to diffusion of hydrogen from the second silicon nitride layer 16.

The second silicon nitride layer 16 is formed over the back surface of the n-type crystalline silicon wafer 11 with the passivation layer 17 and the n-type amorphous silicon layer 14 therebetween. The second silicon nitride layer 16 is interposed between the n-type amorphous silicon layer 14 and the p-type amorphous silicon layer 15, and functions as an insulating layer at a portion where the amorphous silicon layers overlap each other. In other words, the second silicon nitride layer 16 is formed over an approximate entire region of the region in which the p-type amorphous silicon layer 14 overlaps over the n-type amorphous silicon layer 14.

Similar to the first silicon nitride layer 12, the second silicon nitride layer 16 is formed including SiN as a main composition. The second silicon nitride layer 16 may include compositions other than SiN such as silicon oxide and silicon oxynitride, but the content of SiN is greater than or equal to 50 weight % with respect to the layer weight, and is desirably greater than or equal to 80 weight % or about 100 weight %. Similar to the first silicon nitride layer 12, the second silicon nitride layer 16 can be formed through CVD or sputtering. A thickness of the second silicon nitride layer 16 is, for example, 30˜100 nm.

The second silicon nitride layer 16 has a higher index of refraction than that of the first silicon nitride layer 12. A ratio of the index of refraction for the light of the wavelength of 633 nm (the index of refraction of the second silicon nitride layer 16/the index of refraction of the first silicon nitride layer 12) is, for example, 1.05˜1.35. In the solar cell 10, the index of refraction of the first silicon nitride layer 12 is kept low at the light receiving surface side of the n-type crystalline silicon wafer 11, to increase the amount of incident light, and the index of refraction of the second silicon nitride layer 16 is set high at the back surface side, to improve the passivation performance.

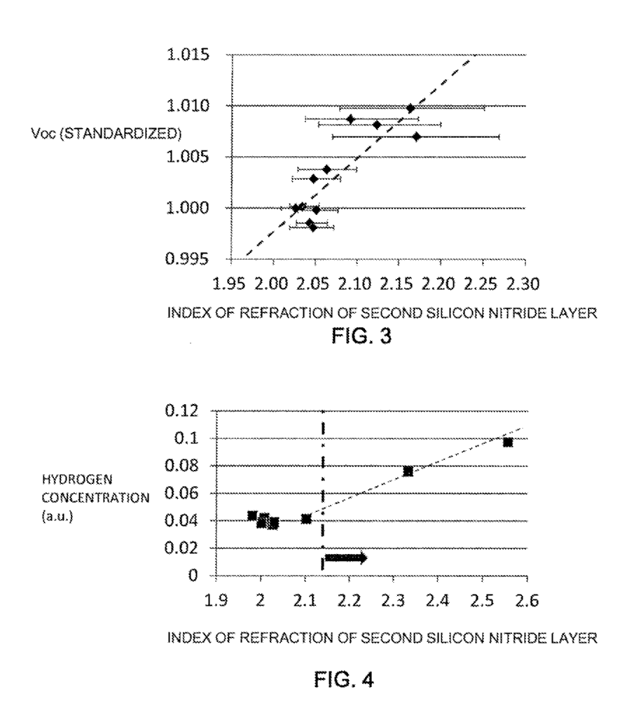

FIG. 3 is a diagram showing a relationship between the index of refraction of the second silicon nitride layer 16 for the light of the wavelength of 633 nm and an open voltage Voc of the solar cell 10. As shown in FIG. 3, the present inventors have found that, by increasing the index of refraction of the second silicon nitride layer 16, Voc of the solar cell 10 can be improved and the output characteristic can be improved. In particular, with the index of refraction of the second silicon nitride layer 16 of greater than or equal to 2.1,the Voc is significantly improved.

The second silicon nitride layer 16 desirably has an index of refraction for the light of the wavelength of 633 nm (hereinafter also referred to as “index of refraction (633 nm)”) of greater than or equal to 2.1. On the other hand, when the index of refraction of the second silicon nitride layer 16 is set too high, the stability of film formation may be degraded, and thus, the index of refraction (633 nm) of the second silicon nitride layer 16 is desirably less than or equal to 2.5. A desirable range for the index of refraction (633 nm) of the second silicon nitride layer 16 is 2.1˜2.5, and more desirable range is 2.1˜2.2.

As a desirable method for adjusting the index of refraction of the second silicon nitride layer 16 to the above-described range, a method may be considered in which a concentration of nitrogen radicals in a material gas used in the CVD is reduced. For the film formation of the second silicon nitride layer 16 through CVD, for example, silane (SiH₄) and ammonia (NH₃) are used as the material gas. By reducing a gas flow rate ratio, NH₃/SiH₄, the index of refraction of the second silicon nitride layer 16 can be increased. Alternatively, the film properties of the second silicon nitride layer 16 may also be changed by changing a temperature, a pressure, or the like during the film formation. For example, when the temperature during the film formation is increased, the index of refraction of the second silicon nitride layer 16 tends to become higher.

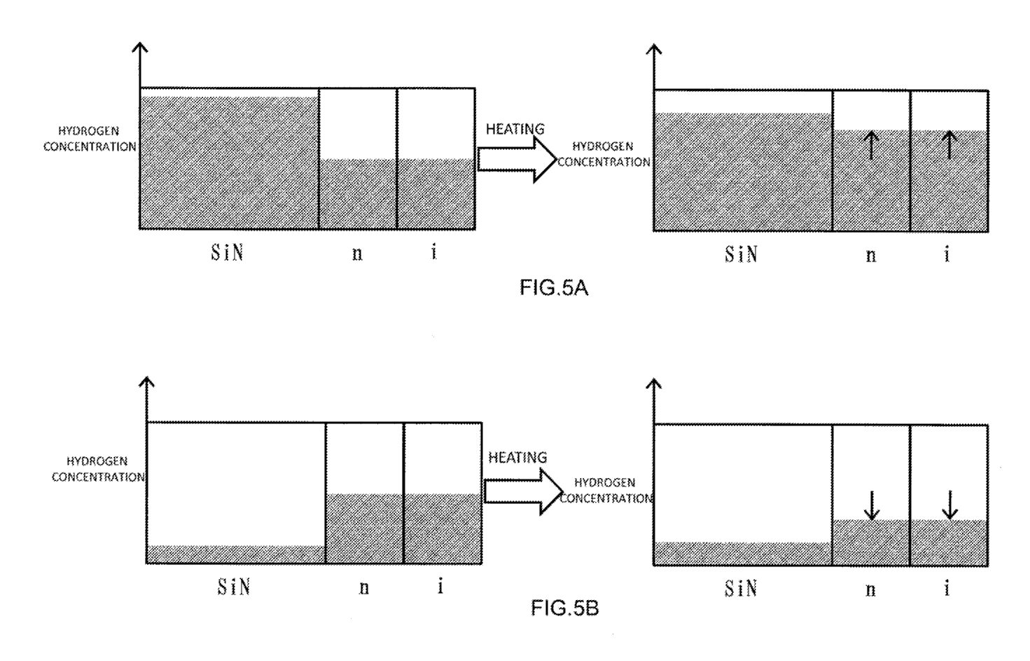

FIG. 4 is a diagram showing a relationship between the index of refraction (633 nm) of the second silicon nitride layer 16 and a hydrogen concentration. Here, the hydrogen concentration of the second silicon nitride layer 16 is a relative value measured by a Fourier transform infrared spectrophotometer (FT-IR). As shown in FIG. 4, when the index of refraction of the second silicon nitride layer 16 is increased, the hydrogen concentration of the second silicon nitride layer 16 is increased. More specifically, when the index of refraction of the second silicon nitride layer 16 is less than 2.1, the hydrogen concentration is approximately unchanging with the increase in the index of refraction, and a proportionality relationship is observed between the hydrogen concentration and the index of refraction in a range of the index of refraction of greater than or equal to 2.1.

The second silicon nitride layer 16 has a higher hydrogen concentration than the first silicon nitride layer 12, and the second silicon nitride layer 16 contains hydrogen, for example, in a concentration of 1.0×10²²˜2.5×10²² atoms/cm³. As the Voc of the solar cell 10 significantly improves at the index of refraction of 2.1 where the hydrogen concentration starts to increase, as described above, it can be considered that the hydrogen concentration of the second silicon nitride layer 16 contributes to the improvement of the Voc.

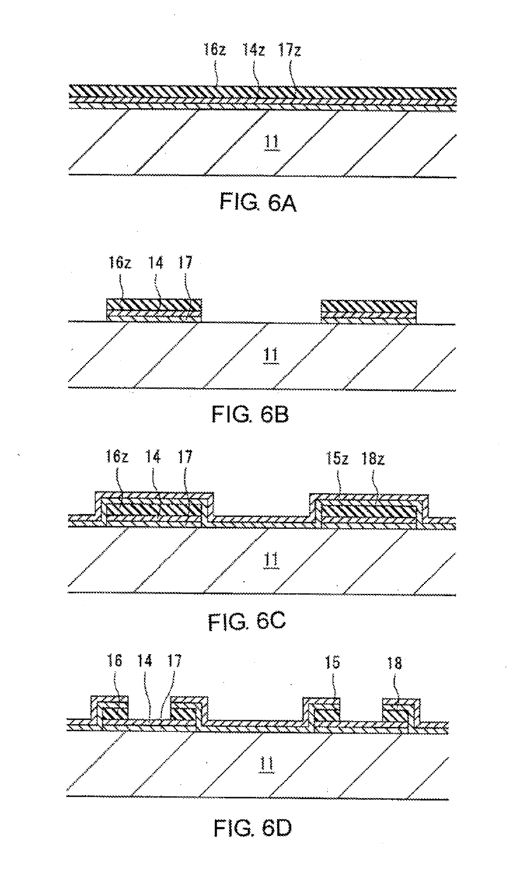

FIG. 5A is a diagram showing a relationship between the hydrogen concentration of the second silicon nitride layer 16 and hydrogen concentrations of the n-type amorphous silicon layer 14 and the passivation layer 17. FIG. 5B shows an example of the related art for comparison purposes. As shown in. FIGS. 5A and 5B, the second silicon nitride layer 16 has a higher index of refraction and a higher hydrogen concentration compared to the silicon nitride layer of the solar cell of the related art. To the n-type amorphous silicon layer 14 and the passivation layer 17 in contact with the second silicon nitride layer 16 having the higher hydrogen concentration, a part of hydrogen diffuses from the second silicon nitride layer 16 by, for example, heat applied during the film formations of the p-type amorphous silicon layer 15 and the passivation layer 18. With this process, it may be considered that the hydrogen concentrations of the n-type amorphous silicon layer 14 and the passivation layer 17 are increased, the passivation performance in the n-type region is improved, and the output characteristic of the solar cell 10 is improved.

As will be described in detail later, during the film formations of the p-type amorphous silicon layer 15 and the passivation layer 18, the entirety of the n-type amorphous silicon layer 14 and the passivation layer 17 is covered by the second silicon nitride layer 16. Because of this, hydrogen diffuses approximately uniformly over the entirety of the n-type amorphous silicon layer 14 and the passivation layer 17, and the hydrogen concentrations of the layers may be considered to become approximately uniform over the entire layer.

On the contrary, in the solar cell of the related art, because the hydrogen concentration of the silicon nitride layer is low, in an opposite manner from the above, hydrogen of the n-type amorphous silicon layer and the passivation layer diffuses into the silicon nitride layer, and the hydrogen concentrations of the n-type amorphous silicon layer and the passivation layer may be considered to become lower than that during film formations. As a method of increasing the hydrogen concentration of the n-type amorphous silicon layer 14, a method may be considered in which a large amount of hydrogen is added during film formation of the silicon layer, but such a method results in a disadvantage that hydrogen diffuses into the n-type crystalline silicon wafer 11 and generates defects, during the film formation of the silicon layer. In other words, in order to improve the passivation performance of the n-type region and to improve the output characteristic of the cell, it may be considered that the diffusion of hydrogen from the second silicon nitride layer 16 to the n-type amorphous silicon layer 14 and the passivation layer 17 is important.

The second silicon nitride layer 16 has a lower density than the first silicon nitride layer 12. The density of the second silicon nitride layer 16 is, for example, 2.3˜2.7 g/cm³, and is desirably less than 2.7 g/cm³. On the other hand, the density of the first silicon nitride layer 12 is, for example, 2.7˜2.9 g/cm³. Note that when the index of refraction of the silicon nitride layer is increased, the density tends to be reduced. FIGS. 1 and 2 are again referred to. The collector electrode 20 is formed over the n-type amorphous silicon layer 14, and comprises a plurality of finger portions 21 which extend approximately parallel to each other, and a bus bar portion 22 which extends approximately perpendicularly to the finger portions 21 and connects ends, in a longitudinal direction, of the finger portions 21. The collector electrode 30 is formed over the p-type amorphous silicon layer 15. Similar to the collector electrode 20, the collector electrode 30 comprises a plurality of finger portions 31 and a bus bar portion 32. Over the back surface of the n-type crystalline silicon wafer 11, the finger portions 21 and 31 extend in the α direction, and the bus bar portions 22 and 32 extend in the β direction.

The finger portions 21 and 31 are alternately provided in the β direction. The finger portion 31 is formed in a wider width than the finger portion 21. The collector electrodes 20 and 30 have a comb shape in the plan view in which the collector electrodes interdegitate each other with a groove 35 formed over the second silicon nitride layer 16 therebetween. To the bus bar portions 22 and 32, a wiring member is attached when the solar cells 10 are connected in series to form a module.

The collector electrodes 20 and 30 may be formed using a conductive paste, but are desirably formed by electroplating. The collector electrodes 20 and 30 are formed from metals such as, for example, nickel (Ni), copper (Cu), silver (Ag), or the like, and may be a layered structure of a Ni layer and a Cu layer, or a tin (Sn) layer may be provided on an uppermost surface in order to improve corrosion resistivity. Thicknesses of the collector electrodes 20 and 30 are, for example, 50 nm˜1 μm, and the collector electrode 20 is formed thicker than the collector electrode 30.

The solar cell 10 further comprises a transparent conductive layer 23 formed between the n-type amorphous silicon layer 14 and the collector electrode 20, and a transparent conductive layer 33 formed between the p-type amorphous silicon layer 15 and the collector electrode 30. The transparent conductive layers 23 and 33 are separated from each other by the groove 35, similar to the collector electrodes 20 and 30. The transparent conductive layers 23 and 33 are formed from, for example, a transparent conductive oxide (IWO, ITO, or the like) in which a metal oxide such as indium oxide (In₂O₃) and zinc oxide (ZnO) is doped with tungsten (W), tin (Sn), antimony (Sb) or the like. Thicknesses of the transparent conductive layers 23 and 33 are, for example, 30˜500 nm.

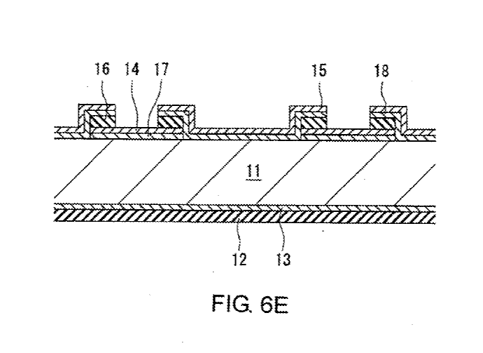

FIGS. 6A-6E are diagrams for explaining an example method of manufacturing the solar cell 10 having the above-described structure. In FIGS. 6A˜6C, a reference sign “z” is attached to the reference numerals of the layers before the layers are patterned into their final shapes. In the manufacturing process of the solar cell 10, first, the n-type crystalline silicon wafer 11 over which the texture structure is formed is prepared. For the n-type crystalline silicon wafer 11, for example, an n-type monocrystalline silicon wafer, in which the texture structure is formed only over a surface which becomes the light receiving surface, is used.

As shown in FIG. 6A, over the other surface which becomes the back surface of the n-type crystalline silicon wafer 11, a passivation layer 17z, an n-type amorphous silicon layer 14z, and a second silicon nitride layer 16z are formed in this order. These layers are formed over approximately entire region of the back surface of the n-type crystalline silicon wafer 11.

The passivation layer 17z, the n-type amorphous silicon layer 14z, and the second silicon nitride layer 16z are formed through CVD or sputtering, as described above. For the film formation of the passivation layer 17z (similarly for the passivation layers 13 and 18) through CVD, for example, material gas in which silane is diluted by hydrogen is used. Further, in the case of the n-type amorphous silicon layer 14z, for example, material gas in which phosphine (PH₃) is added to silane, and the mixture is diluted by hydrogen, is used. By changing a mixture concentration of phosphine, the dopant concentration of the n-type amorphous silicon layer 14z can be adjusted.

For the film formation of the second silicon nitride layer 16z (similarly for the first silicon nitride layer 12) through CVD, silane and ammonia are used as the material gas. In this case, a flow rate ratio of ammonia/silane gas is lowered, to increase the index of refraction of the second silicon nitride layer 16z. In the manufacturing process of the solar cell 10, the flow rate ratio of ammonia/silane gas during the film formation of the second silicon nitride layer 16z is set lower than a flow rate ratio of ammonia/silane gas during the film formation of the first silicon nitride layer 12. With this configuration, the index of refraction of the second silicon nitride layer 16 can be set higher than the index of refraction of the first silicon nitride layer 12.

Next, as shown in FIG. 6B, the layers formed over the back surface of the n-type crystalline silicon wafer 11 are patterned. The second silicon nitride layer 16z is etched, for example, using a resist film as a mask, and using an aqueous solution of hydrogen fluoride (HF). After the etching of the second silicon nitride layer 16z is completed, the exposed n-type amorphous silicon layer 14z and passivation layer 17z are etched using the patterned second silicon nitride layer 16z as a mask, and using an aqueous solution of sodium hydroxide (NaOH). With this process, the passivation layer 17, the n-type amorphous silicon layer 14, and the second silicon nitride layer 16z which are patterned are formed over the back surface of the n-type crystalline silicon wafer 11.

Next, as shown in FIG. 6C, a passivation layer 18z and a p-type amorphous silicon layer 15z are formed in this order over an approximate entire region of the back surface of the n-type crystalline silicon wafer 11 including the patterned second silicon nitride layer 16z. For the film formation of the p-type amorphous silicon layer 15, for example, material gas in which diborane (B₂H₆) is added to silane and the mixture is diluted by hydrogen, is used. As described above, it is considered that, by the heat applied during the film formations of the p-type amorphous silicon layer 15z and the passivation layer 18z, hydrogen in the second silicon nitride layer 16z diffuses into the n-type amorphous silicon layer 14 and the passivation layer 17.

Next, as shown in FIG. 6D, the p-type amorphous silicon layer 15z and the passivation layer 18z formed over the second silicon nitride layer 16z are patterned, and exposed portions of the second silicon nitride layer 16 are etched. For the etching of the p-type amorphous silicon layer 15z, in general, an etching solution of a higher concentration is used than the aqueous solution of NaOH used for the etching of the n-type amorphous silicon layer 14z. A region etched in this process is a region in which the transparent conductive layer 23 and the collector electrode 20 are formed in subsequent processes. With this process, the passivation layer 18, the p-type amorphous silicon layer 15, and the second silicon nitride layer 16 which are patterned are formed over the back surface of the n-type crystalline silicon wafer 11.

Next, as shown in FIG. 6E, the passivation layer 13 and the first silicon nitride layer 12 are formed in this order through CVD or sputtering over the other surface (light receiving surface) of the n-type crystalline silicon wafer 11. As described above, the first silicon nitride layer 12 and the passivation layer 13 are formed over an approximate entire region of the light receiving surface of the n-type crystalline silicon wafer 11. Although not shown in the figures, next, the transparent conductive layer 23 and the collector electrode 20 are formed over the n-type amorphous silicon layer 14, and the transparent conductive layer 33 and the collector electrode 30 are formed over the p-type amorphous silicon layer 15, to obtain the solar cell 10.

While the foregoing has described what are considered to be the best mode and/or other examples, it is understood that various modifications may be made therein and that the subject matter disclosed herein may be implemented in various forms and examples, and that they may be applied in numerous applications, only some of which have been described herein. It is intended by the following claims to claim any and all modifications and variations that fall within the true scope of the present teachings.

1. A solar cell comprising:
a crystalline silicon wafer;
a first silicon nitride layer including silicon nitride as a main composition, and formed over a light receiving surface of the crystalline silicon wafer;
a first amorphous silicon layer of a first conductivity type, formed over a first region of a back surface of the crystalline silicon wafer;
a second silicon nitride layer including silicon nitride as a main composition, and formed over a part of the first amorphous silicon layer; and
a second amorphous silicon layer of a second conductivity type, formed over a second region of the back surface of the crystalline silicon wafer and over the second silicon nitride layer, wherein
the second silicon nitride layer has a higher index of refraction than the first silicon nitride layer.

2. The solar cell according to claim 1, wherein
the crystalline silicon wafer is an n-type crystalline silicon wafer,
the first amorphous silicon layer is formed including n-type amorphous silicon as a main composition, and
the second amorphous silicon layer is formed including p-type amorphous silicon as a main composition.

3. The solar cell according to claim 2, further comprising:
a passivation layer including, as a main composition, substantially intrinsic silicon or amorphous silicon having a lower concentration of an n-type dopant than the n-type amorphous silicon of the first amorphous silicon layer, and formed between the crystalline silicon wafer and the first amorphous silicon layer.

4. The solar cell according to claim 1, wherein
the second silicon nitride layer has an index of refraction for light of a wavelength of 633 nm of greater than or equal to 2.1.

5. The solar cell according to claim 4, wherein
the second silicon nitride layer has an index of refraction for the light of the wavelength of 633 nm of less than or equal to 2.5.

6. The solar cell according to claim 1, wherein
the second silicon nitride layer has a higher hydrogen concentration than the first silicon nitride layer.

7. The solar cell according to claim 1, wherein
the second silicon nitride layer has a lower density than the first silicon nitride layer.
